(19) United States
(12) Patent Application Publication
(10) Pub. No.: US 2025/0374830 A1
(43) Pub. Date: Dec. 4, 2025

(54) ANNEALING-BASED PIEZOELECTRIC ENHANCEMENT IN III-NITRIDE MATERIALS AND ALLOYS

(71) Applicant: The Regents of the University of Michigan, Ann Arbor, MI (US)

(72) Inventors: Shubham Mondal, Ann Arbor, MI (US); Md Mehedi Hasan Tanim, Ann Arbor, MI (US); Zetian Mi, Ann Arbor, MI (US)

(21) Appl. No.: 19/225,264

(22) Filed: Jun. 2, 2025

Related U.S. Application Data
(60) Provisional application No. 63/654,305, filed on May 31, 2024.

(51) Int. Cl. H10N 30/04; H10N 30/074; H10N 30/853

(52) U.S. Cl. CPC H10N 30/04; H10N 30/074; H10N 30/853

(57) ABSTRACT

A method of fabricating a heterostructure includes providing a substrate, forming a piezoelectric layer supported by the substrate, the piezoelectric layer including a III-nitride material or an alloy thereof, and annealing the piezoelectric layer at an anneal temperature higher than a temperature at which forming the piezoelectric layer is implemented by about 50 degrees Celsius to about 400 degrees Celsius.

### CROSS-REFERENCE TO RELATED APPLICATION

This application claims the benefit of U.S. provisional application entitled “Annealing-Based Piezoelectric Enhancement in III-Nitride Materials and Alloys,” filed May 31, 2024, and assigned Ser. No. 63/654,305, the entire disclosure of which is hereby expressly incorporated by reference.

### STATEMENT REGARDING FEDERALLY SPONSORED RESEARCH OR DEVELOPMENT

This invention was made with government support under Contract No. HR0011-23-9-0018 awarded by the U.S. Department of Defense, Defense Advanced Research Projects Agency. The government has certain rights in the invention.

### BACKGROUND OF THE DISCLOSURE

### Field of the Disclosure

The disclosure relates generally to piezoelectric Group III-nitride materials.

### Brief Description of Related Technology

Piezoelectricity is the generation of electrical charge in certain materials upon mechanical stress. In crystalline materials with no inversion symmetry, piezoelectricity is produced due to electrochemical interaction between the electrical and mechanical states of the materials. The piezoelectric effect is also reversible, i.e., a piezoelectric material can generate mechanical strain when there is an applied field. Since the first demonstration of direct piezoelectricity effect by P. Curie and J. Curie in 1880, piezoelectricity has been widely utilized in applications such as high-voltage and high-power sources, sensors, actuators, frequency standard, surgery, and ultrasound medical devices. Thin film piezoelectric materials have also been explored and intensively studied to advance a broad range of devices and systems, including next-generation microelectromechanical systems (MEMS) as well as acoustic wave resonators and filters for future communication technologies. Piezoelectric materials have also shaped communication technologies like 5G and beyond and empowered the evolution of sensing applications such as electroacoustic and immunosensors, microphones, touch-sensitive screens, and activity monitors in smart wearables, to name just a few.

The most prevalent and researched piezoelectric materials include ferroelectric ceramics such as Pb(ZrₓTi₁₋ₓ)O₃ (PZT), barium titanate (BaTiO₃), and other perovskite titanates. While these materials exhibit good piezoelectric properties, the materials are incompatible with existing CMOS processes, and their low Curie temperatures (generally in the range of 300-400° C.) result in a sharp deterioration in their ferroelectric and piezoelectric properties at higher temperatures. Additionally, PZT poses environmental hazards due to its high toxicity and volatility at high temperatures.

Aluminum nitride (AlN) has emerged as a promising platform for a wide range applications, including MEMS/nanoelectromechanical system devices as well as high frequency resonators and filters, due to its high Curie temperature (about 1150° C.), minimal acoustic and dielectric losses, elevated acoustic wave velocity, non-toxicity, and seamless integration with the established CMOS, silicon-manufacturing processes. However, pure AlN thin films exhibit a limited natural piezoelectric response in contrast to materials like PZT.

While AlN has a low piezoelectricity modulus (d₃₃=5.5 pC/N), the introduction of one or more doping elements can significantly enhance d₃₃. Studies have shown that doping AlN can enhance its piezoelectric properties. Wurtzite ScₓAl₁₋ₓN represents one such alloy that amplifies the piezoelectric responsiveness of AlN, achieving a 400% enhancement at approximately 50% Sc composition based on theoretical prediction. The significantly enhanced piezoelectric response is primarily due to the energy landscape flattening as a result of competition between the hexagonal and the parent wurtzite phase with increasing Sc content.

However, attaining high-quality crystal structures of ScAlN becomes progressively arduous with increasing Sc content, thereby constraining the realization of the exceptional piezoelectric properties predicted by theory. Moreover, high Sc content levels also lead to phase transitions, which can eliminate any piezoelectric response from the material. Consequently, current practical device implementations are largely based on ScAlN structures with relatively lower Sc concentrations (about 20%), which can exhibit a relatively low level of defects and material imperfections while achieving a moderate enhancement of d₃₃ values in the range of 10-15 pC/N.

### SUMMARY OF THE DISCLOSURE

In accordance with one aspect of the disclosure, a method of fabricating a heterostructure includes providing a substrate, forming a piezoelectric layer supported by the substrate, the piezoelectric layer including a III-nitride material or an alloy thereof, and annealing the piezoelectric layer at an anneal temperature higher than a temperature at which forming the piezoelectric layer is implemented by about 50 degrees Celsius to about 400 degrees Celsius.

In accordance with another aspect of the disclosure, a method of fabricating a heterostructure includes providing a substrate, growing a piezoelectric layer supported by the substrate at a growth temperature less than about 400 degrees Celsius, the piezoelectric layer including a III-nitride material or an alloy thereof, and annealing the piezoelectric layer at an anneal temperature higher than the growth temperature by about 50 degrees Celsius to about 400 degrees Celsius.

In connection with any one of the aforementioned aspects, the devices and/or methods described herein may alternatively or additionally include or involve any combination of one or more of the following aspects or features. Forming the piezoelectric layer includes implementing a molecular beam epitaxy (MBE) procedure. Annealing the piezoelectric layer is implemented in a vacuum. The temperature at which forming the piezoelectric layer is implemented is less than about 400 degrees Celsius. The anneal temperature is less than about 400 degrees Celsius. The anneal temperature falls in a range from about 250 degrees Celsius to about 450 degrees Celsius. The anneal temperature is higher than the temperature at which forming the piezoelectric layer is implemented by about 100 degrees Celsius to about 300 degrees Celsius. Annealing the piezoelectric layer is implemented for a duration falling in a range from about 30 minutes to about 3 hours. The piezoelectric layer includes AlN or AIBN. The piezoelectric layer includes a III-nitride alloy, the III-nitride alloy including a Group IIIB element. The III-nitride alloy is ScAlN. The III-nitride alloy has a scandium composition above about 20%. The piezoelectric layer is in contact with the substrate. The substrate includes silicon. Growing the piezoelectric layer includes implementing a molecular beam epitaxy (MBE) procedure. The piezoelectric layer includes a III-nitride alloy, the III-nitride alloy having a scandium composition above about 20%.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts graphical plots of (a) the piezoelectric coefficient d₃₃ for various annealing temperatures for MBE-grown ScAlN layers, showing a maximum enhancement at an annealing temperature T of 400° C., and (b) the piezoelectric coefficient d₃₃ for various annealing durations at an annealing temperature of 400° C., showing a maximum enhancement at a duration of 2 hours.

FIG. 2 depicts atomic force microscopy (AFM) images of both (a) pristine (as grown) and (b) annealed ScAlN layers, in which the ScAlN layer was annealed at 400° C. for 2 hours.

FIG. 3 is a schematic view of a heterostructure having a piezoelectric ScAlN layer with annealing-based piezoelectric enhancement in accordance with one example.

FIG. 4 is a flow diagram of a method of fabricating a heterostructure having a piezoelectric ScAlN layer with annealing-based piezoelectric enhancement in accordance with one example.

The embodiments of the disclosed methods and devices may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Methods of fabricating heterostructures having a piezoelectric layer with enhanced piezoelectric performance are described. The enhancement is achieved via a post-formation anneal of the piezoelectric layer. The piezoelectric layer is composed of, or otherwise includes, a III-nitride material or an alloy thereof. In some cases, the piezoelectric layers are grown via MBE. The piezoelectric layer may be annealed after growth or other formation at a temperature about 50 to about 400° C. above the temperature at which the layer is grown or otherwise formed.

Methods of fabricating heterostructures and devices include implementation of a scalable, post-growth high temperature annealing procedure to dramatically enhance the piezoelectric response of a III-nitride material or alloy such as ScAlN. For MBE-grown examples of Sc_{0.18}A_{0.82}N, the piezoelectric coefficient d₃₃ was enhanced from 13.1 pC/N for the as grown sample to 23.7 pC/N with a 2 hour annealing at 400° C., representing an 80% enhancement. No observable deterioration of the surface morphology was observed in atomic force microscopy (AFM) images comparing the film before and after annealing.

The piezoelectric coefficient d₃₃ value may be further enhanced via adjustment or configuration of other aspects of the disclosed methods. For instance, one or more parameters of the growth or formation process may be adjusted, including, for instance, Sc composition and the incorporation of other IIIB elements, e.g., Y and La.

The disclosed methods may include low temperature epitaxial growth (e.g., growth at CMOS compatible temperatures, such as less than 400 degrees C.) of the piezoelectric layers. For instance, in examples involving MBE growth, the growth temperature was sufficiently below 400° C. (e.g., 150° C.) such that the anneal temperature was also below 400° C. In some cases, the piezoelectric layers are single crystalline after such epitaxial growth.

Although described in connection with MBE-based examples, additional or alternative growth, deposition, or other processes may be used to form the piezoelectric layers. For instance, metal-organic chemical vapor deposition (MOCVD) and hydride vapor phase epitaxy (HVPE) growth procedures may be used. Still other procedures may be used, including, for instance, atomic layer epitaxy or deposition and pulsed laser deposition.

The piezoelectric layers may be grown or otherwise formed on various substrates. The substrate may or may not be uniform. For instance, the substrate may include a template layer for the piezoelectric layer. In some cases, the piezoelectric layer is grown or formed on a silicon substrate. Alternative or additional templates or substrates may be used, including, for instance, metal templates and/or substrates, such as aluminum and molybdenum, as well as non-metal substrates, such as SiC, diamond, GaN and AlN.

The formation and annealing of the piezoelectric layers may be implemented in the same reaction or other process chamber, which can avoid the formation of surface oxides and the incorporation of interface impurities. Additional layers or other structures of the heterostructure or device may also be deposited or otherwise formed in the same reaction or other process chamber.

The piezoelectric layers formed via the disclosed methods may be used to fabricate a broad range of devices, including, for instance, acoustic resonators/filters, MEMS devices, acoustic or optical modulators, waveguides, transistors, ultrasonic devices and systems, and quantum photonic circuits or other devices. The heterostructures of the devices may accordingly include a wide variety of multi-layer structures.

Although described in connection with examples of epitaxially grown ScₓAl₁₋ₓN layers, the disclosed methods and devices may be applied to a variety of III-nitride materials or alloys thereof, including, for instance, AlN, ScGaN, ScInN, AIBN, and their alloys. The disclosed methods and devices may thus include or involve the incorporation of scandium into other III-nitride wurtzite structures. For instance, the disclosed methods and devices may include or involve one or more quaternary alloys, such as ScₓAl_{y}Ga_{1-x-y}N. The disclosed methods and devices are also not limited to III-nitride alloys including scandium. For instance, the III-nitride alloys may include additional or alternative group IIIB elements, such as yttrium (Y) and lanthanum (La).

The configuration, construction, fabrication, and other characteristics of the heterostructures may also vary from the examples described. For instance, the heterostructures may include any number of III-nitride-based layers of piezoelectric and non-piezoelectric nature. One or more layers may be additionally or alternatively ferroelectric.

Although described in connection with examples having a Sc composition of 18%, the compositions of the III-nitride alloys of the example devices and heterostructures may vary. Indeed, varying (e.g., increasing) the Sc or other IIIB composition may be used to attain higher levels of piezoelectric performance. For instance, the Sc or other IIIB composition may be increased to a level (e.g., Sc content above about 20%) at which crystal quality and/or piezoelectric functionality may be otherwise compromised.

Examples fabricated via the disclosed methods included 100 nm ScAlN layer grown at a substrate temperature of 150° C. by plasma-assisted MBE with a Sc content of 18% on highly doped n-type Si (111) substrates. The examples underwent a thorough solvent cleaning procedure, after which annealing was performed using an Angstrom Engineering (AE) Furnace, a high-temperature furnace with the ability to anneal under selected environmental conditions. In these cases, the sample was placed into the annealing tube, and then the tube was evacuated for 5 minutes to eliminate all remaining air. When the pressure reached 10 mTorr, the temperature was subsequently increased and was measured using both internal and external thermocouples. After the temperature reached a steady state, the example was subjected to baking for the intended duration. Following the baking process, the furnace system gradually decreased the temperature. The temperature profile for the anneal may vary in other cases. Additionally, to further verify the d₃₃ results obtained from the piezoresponse force microscopy (PFM) measurements, electrodes were patterned on the ScAlN surface by standard photolithography.

Further details on example growth conditions and other fabrication procedures or parameters not otherwise addressed herein are set forth in WO 2023/022768 (“Epitaxial Nitride Ferroelectronics”), WO 2023/164071 (“Epitaxial Nitride Ferroelectronic Devices”), WO 2024/091933 (“Low Temperature Epitaxy of Polar Semiconductors”), P. Wang, et al., “Fully epitaxial ferroelectric ScAlN grown by molecular beam epitaxy,” Applied Physics Letters, vol. 118, p. 223504 (2021), D. Wang et al., “An Epitaxial Ferroelectric ScAlN/GaN Heterostructure Memory,” Advanced Electronic Materials, p. 2200005 (2022), D. Wang, et al., “Fully epitaxial ferroelectric ScGaN grown on GaN by molecular beam epitaxy,” Appl Phys Lett 119 (11), 111902 (2021), D. Wang et al., “Impact of dislocation density on the ferroelectric properties of ScAlN grown by molecular beam epitaxy,” Appl Phys Lett 121 (4), 042108 (2022), P. Wang et al., “Quaternary alloy ScAlGaN: A promising strategy to improve the quality of ScAlN,” Appl Phys Lett 120 (1), 012104 (2022), and P. Wang et al. “Ferroelectric Nitride Heterostructures on CMOS Compatible Molybdenum for Synaptic Memristors,” ACS Appl. Mater. Interfaces 2023, 15, 14, 18022-18031 (2023), the entire disclosures of which are hereby incorporated by reference.

A laser doppler vibrometry (LDV) system was used to obtain and validate the d₃₃ measurements. The LDV system is equipped with a laser beam (helium-neon, λ=633 nm) manufactured by Polytec GmbH in conjunction with a ferroelectric tester (Precision Multiferroic Tester, Radiant Technologies, Inc.), which electrically stimulates the films. In addition, to mitigate any possible ambient vibrational noise that may lead to a low signal-to-noise ratio (SNR), the apparatus is positioned on an active vibration-isolation platform inside an acoustic enclosure. Before conducting the LDV measurements, electrodes specifically built for the measurements were deposited on the surface of the piezoelectric films. The electrical excitation of the electrodes is achieved using two tungsten needles. The voltage amplitude was set at 10 V, and the frequency employed was 20 KHz.

The backside of the substrate was grounded electrically. After applying a bias, the surface displacement was recorded. Additionally, bias-dependent measurements are conducted to assess the cumulative impact of both the stage and the enclosure. The measured displacement values were consistent across all cases, hence nullifying the impact of any ambient-induced noise on the measured displacement. The surface morphology of the films was analyzed using a Bruker ICON Atomic Force Microscopy (AFM) system.

The piezoelectric response exhibited by AlN films is strongly associated with various crystal properties, including but not limited to the orientation of the c-axis, the distribution of polar grains, and the presence of defects within the films. The extent to which annealing enhances crystallinity of the ScAlN thin films was accordingly investigated. The examples were annealed under varying conditions to identify useful (e.g., ideal) annealing parameters for enhancing the piezoelectric response of ScAlN samples.

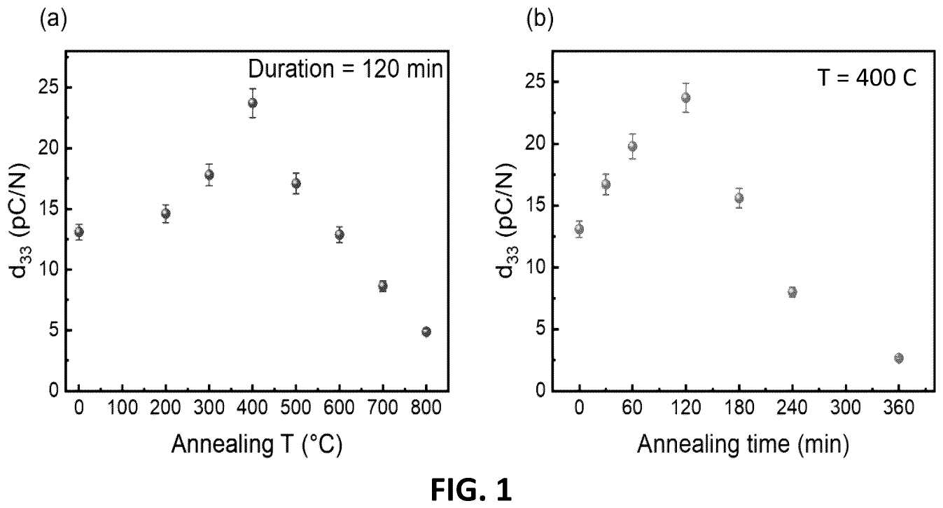

The evolution of d₃₃ for various annealing conditions for the MBE grown ScAlN examples is depicted in FIG. 1. The data points in the plots of FIG. 1 correspond to the as grown samples, annealed at the specific condition, with the error bar highlighting the variance in observed values across multiple measurements. As shown in FIG. 1, part a, an as-grown SC_{0.18}Al_{0.82}N MBE-grown layer without annealing was found to have a piezoelectric coefficient d₃₃ of 13.1 pC/N from PFM and LDV measurements.

FIG. 1, part a, shows that, with an increase in annealing temperature, the piezoelectric coefficient d₃₃ enhances and reaches a maximum of 23.7 pC/N at an annealing temperature of 400° C. for a duration of 2 hours in vacuum, beyond which it drops gradually with an increase in annealing temperature. The maximum was thus reached at an annealing temperature about 250° C. greater than the MBE growth temperature.

The difference in growth and annealing temperatures may vary in other cases. For instance, the annealing temperature may be about 100° C. to about 300° C. greater than the growth or other formation temperature. It should be noted that the difference in temperatures may vary somewhat in connection with different fabrication systems and/or measurement techniques. In view of such deviations and the data described above, the annealing temperature may accordingly be about 50° C. to about 400° C. greater than the growth or other formation temperature.

Keeping the annealing temperature fixed at 400° C., the annealing duration was varied from 0.5 hour to 6 hours to analyze the evolution of the piezoelectric response with annealing duration. As shown in FIG. 1, part b, the piezoelectric response increases with annealing duration, with a maximum d₃₃ of 23.7 pC/N obtained for an annealing duration of 120 mins (2 h), an 80% increase compared to 13.1 pC/N for the as grown sample. The piezoelectric response starts dropping sharply beyond 2 hours. To confirm the d₃₃ values acquired through PFM measurements, LDV measurements were obtained for both the as-grown and optimally annealed samples. The LDV results revealed a d₃₃ value of 12.9 pm/V for the as-grown sample and a peak d₃₃ value of 22.6 pm/V for the sample annealed at 400° C. for 2 hours. These findings closely align with those obtained from the PFM measurements, providing additional evidence to support the enhancement achieved through annealing.

As the piezoelectric coefficient depends on e₃₃/C₃₃, the strain sensitivity of the internal parameter, defined as

$$\frac{\partial u}{\partial ε} ,$$

is a significant factor that can determine the piezoelectric response of a material. A large

$$\frac{\partial u}{\partial ε}$$

value means that that the displacement of atoms in the alloy is large when it experiences external strain. As annealing may significantly impact the strain state of the material, this factor may contribute significantly to the enhancement of e₃₃, thereby increasing d₃₃. Moreover, lattice softening, change in metal-N bond length, and Born effective charge (Z₃₃) owing to annealing may also be responsible for the remarkable increase in d₃₃.

The effects on surface morphology were also investigated. High-temperature annealing (HTA) is commonly linked to the degradation of surface morphology. However, the annealing temperature used for the above-described examples was relatively low (e.g., 400° C.), such that little to no impact on the surface morphology was realized. To assess the impact of high temperature annealing on the surface roughness of the MBE-grown ScAlN films, a comparative analysis using Atomic Force Microscopy (AFM) images was conducted on both non-annealed (or pristine) and post-annealed samples. The annealed samples were annealed at 400° C. for 2 hours.

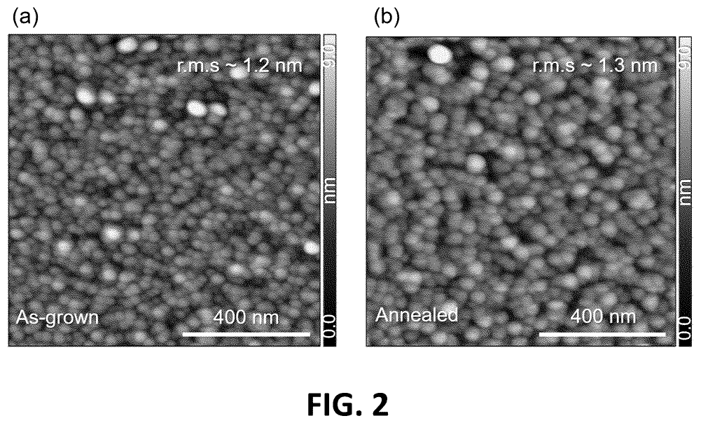

The results of analysis for the non-annealed and annealed samples are illustrated in FIG. 2, parts (a) and (b), respectively. The AFM images reveal that there is no significant deterioration in the surface morphology for the samples annealed under the example conditions. The as-grown ScAlN sample exhibited a root mean square (r.m.s.) roughness of 1.2 nm, whereas the sample annealed at 400° C. for 2 hours displayed a slightly higher r.m.s. roughness of 1.3 nm, measured over a scanning area of 1 μm×1 μm, thereby preserving the integrity of the surface morphology to a considerable extent. These results indicate that the optimized annealing process causes significant enhancement in the piezoelectric response while causing minimal changes in surface roughness.

The above-described examples demonstrate a scalable and highly effective technique to dramatically enhance the piezoelectric response of III-nitrides and their alloys, such as ScAlN, via annealing (e.g., by employing a high temperature annealing technique). The high piezoelectric response realized in the ScAlN examples, together with the scalability and cost-effectiveness of the approach and its compatibility with CMOS integration processes (e.g., process temperatures below about 400° C.), support the use of ScAlN and other IIIB doped nitride semiconductors in a broad range of applications, ranging from electronic, acoustic, photonic, quantum, and energy harvesting devices and systems.

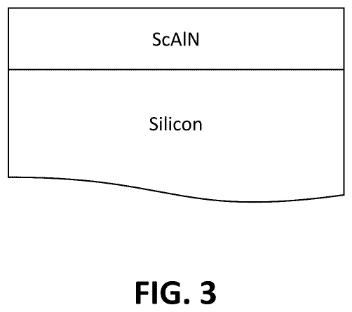

FIG. 3 depicts a heterostructure with a piezoelectric layer having an enhanced piezoelectric coefficient in accordance with one example. As described herein, the piezoelectric layer may be composed of, or otherwise include, a III-nitride material or alloy thereof. The heterostructure may be fabricated via the methods described herein. In this example, the piezoelectric layer is supported by a silicon substrate. The composition and other characteristics of the substrate may vary. For instance, alternative or additional materials may be used, including, for instance, a metal.

The heterostructure may include any number of additional layers or other structures. For instance, one or more electrodes may be deposited or otherwise formed on the piezoelectric layer and/or substrate. The heterostructure may be combined with any number of other layers or other structures to form a device, or a component or module thereof, having piezoelectric functionality.

The piezoelectric layer may be grown or integrated with an optical waveguide, such as SiNₓ, Si, or LiNbO₃. The piezoelectric layer may also be grown or integrated with a quantum light emitter, such as color centers in diamond or SiC. The piezoelectric layer may also be grown or integrated with other acoustic or optical resonators and filters, including MEMS devices, to achieve enhanced functionality, performance, and/or tunability, and/or a reduced footprint.

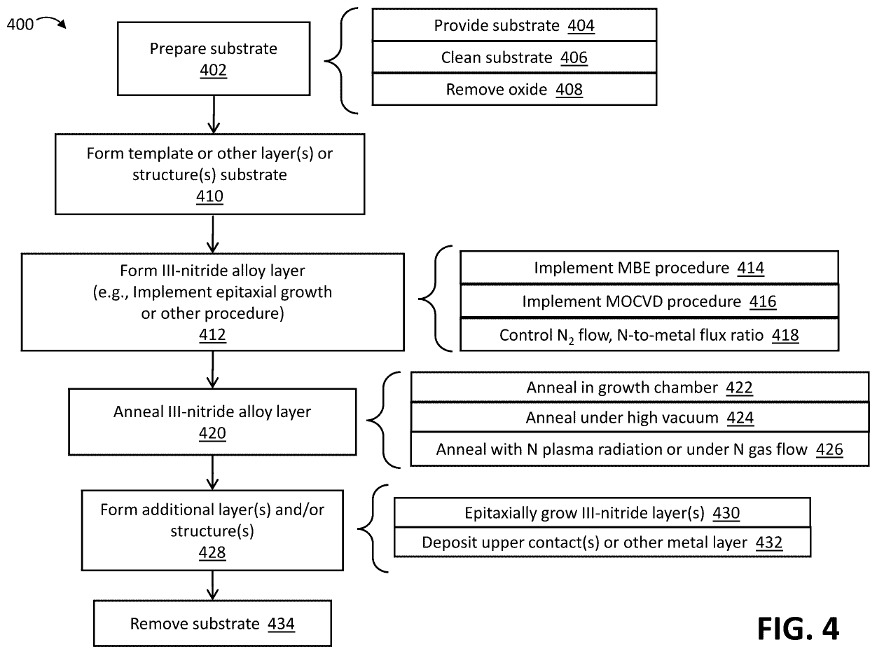

FIG. 4 depicts a method 400 of fabricating a heterostructure having a piezoelectric layer in accordance with one example. As described herein, the piezoelectric layer is composed of, or otherwise includes, a III-nitride material or alloy thereof. The method 400 may be configured such that the piezoelectric layer is formed using low temperatures, e.g., sufficiently low for compatibility with CMOS fabrication. The piezoelectric layer may or may not exhibit ferroelectric behavior. The method 400 may be used to fabricate the examples of devices, heterostructures, and other structures having piezoelectric films or layers described herein, and/or other devices, heterostructures or structures.

The method 400 may begin with an act 402 in which a substrate is prepared and/or otherwise provided. In some cases, the act 402 includes providing a silicon substrate in an act 404. The silicon substrate may have a (111) orientation. The substrate may be patterned or otherwise processed to configure the substrate to reduce defect formation in subsequently grown layers of the heterostructure and/or otherwise improve material quality therein. Such processing may also facilitate the formation of a different regions of the heterostructure.

Alternative or additional substrate materials may be used, including, for instance, sapphire, bulk GaN, bulk AlN, or other semiconductor material. Still other materials may be used, including, for instance, silicon carbide. In still other cases, a metal substrate may be used. For instance, the metal substrate may be composed of, or otherwise include, Al, Pt, and/or Mo.

The substrate may be cleaned in an act 406. In some cases, a native or other oxide layer may be removed from a substrate surface in an act 408. The oxide removal may include multiple steps, including, for instance, an etch step and an annealing step.

The substrate may also be doped. For instance, the substrate may be doped n-type, as described herein. The dopant, profile, and/or doping procedure may vary in accordance with the device or application.

Additional or alternative processing may be implemented in other cases, including, for instance, other doping or deposition procedures. The substrate thus may or may not have a uniform composition. The substrate may be a uniform or composite structure. Any number of layers or structures may be deposited on the substrate prior to the implementation of the acts described below.

The method 400 may include an act 410, in which one or more template or other layers are formed or otherwise provided. In some cases, the template layer is composed of, or otherwise includes, a metal such as Al or Mo. In other cases, the template layer is composed of, or otherwise includes, a III-nitride layer (e.g., GaN) or other semiconductor layer. The template layer is supported by the substrate. In some cases, the template layer is in contact with the substrate. In other cases, one or more buffer or other layers or structures (e.g., CMOS component structures) are disposed between the template layer and the substrate.

In some cases, the act 410 is part of a CMOS fabrication procedure directed to fabricating a CMOS component (e.g., CMOS transistor, diode, etc.) of the device. A number of layers or other structures may be formed during the CMOS fabrication procedure, including, for instance, various types of electrodes, contacts, and other structures. In some cases, one of the structures of the CMOS component may be configured or act as a template layer.

In some cases, the act 610 includes depositing the template layer(s). A wide variety of deposition procedures may be used. The template layer(s) may be patterned and/or otherwise processed in accordance with the configuration of the device.

The act 410 may include the deposition or other formation of one or more other metal layers or structures. For example, a bottom contact may be formed. The number and other characteristics of the metal layers or structures may vary in accordance with the configuration of the device (e.g., the number of terminals).

As described herein, the metal layers or structures may be part of a CMOS component of the device being fabricated. For example, the metal layer or structure may be an electrode of a CMOS transistor, CMOS diode, or other CMOS component.

As described herein, in some cases, the metal layer or structure is formed in a chamber also used for implementation of an epitaxial growth, deposition, or other procedure to form the piezoelectric layer. That is, the same chamber is used to form the metal layer or structure and grow the piezoelectric layer. As a result, the metal layer (or other layer or portion of a heterostructure being formed) is not exposed to an ambient between formation of the metal structure and implementation of the epitaxial growth, deposition, or other formation procedure.

Alternatively, the act 410 may include one or more acts in which a surface treatment procedure is implemented to remove oxide from a surface of a metal or other template layer. In some cases, a polycrystalline metal layer is annealed in a vacuum. The temperature of the annealing may vary, e.g., with the composition of the metal layer and/or other structures of the device (e.g., CMOS component structures). For instance, MoOs has a relatively low melting point (795° C.), in which case annealing above the melting point, e.g., at about 900° C., may be used. The annealing may also improve the surface roughness of the metal layer. In one example involving annealing at 900° C. for 10 minutes, except for the domain boundaries, a smooth surface was observed on each domain. Furthermore, after the high-temperature annealing, the domain boundaries were more uniform with significantly reduced misoriented clusters. The oxide may be removed in additional or alternative ways to achieve a highly ordered atomically smooth surface. For instance, the oxide may be removed via an etching procedure using, e.g., an acid solution, such as hydrochloric acid (HCl) or buffered hydrofluoric acid (BHF).

An epitaxial growth or other procedure is implemented in an act 412 to form a the piezoelectric layer supported by the substrate. As described herein, the piezoelectric layer is composed of, or otherwise includes, a III-nitride material or alloy thereof. The piezoelectric layer may or may not be in contact with the substrate. For instance, the piezoelectric layer may instead be in contact with a template layer. The piezoelectric layer may or may not be single-crystalline at this point. In some cases, the piezoelectric layer is composed of, or otherwise includes, a III-nitride alloy, such as ScAlN. Other piezoelectric III-nitride alloy layers may be grown, including, for instance, alloys of gallium nitride (GaN), indium nitride (InN).

The piezoelectric layer may or may not be ferroelectric. As described herein, the piezoelectric layer may have a wurtzite structure.

The epitaxial growth or other formation procedure may be configured to incorporate scandium and/or another group IIIB element to form an alloy of the III-nitride material. The alloy may thus be ScAlN or YAlN, for example. In some cases, the act 412 includes an act 414 in which an MBE procedure is implemented. In other cases, an MOCVD or other deposition procedure is implemented in an act 416.

In some cases, the act 412 may include an act in which the piezoelectric layer is grown in a chamber in which the template layer is formed. For instance, the same chamber may be used to form a metal or other template layer (e.g., Mo or Al template layer) and grow or otherwise form the piezoelectric layer. As a result, the substrate may remain within, e.g., is not removed from, the epitaxial growth or other chamber between forming the metal or other template layer and growing the single-crystalline semiconductor layer. Exposure to the ambient is thus avoided.

As described herein, the epitaxial growth or other procedure may be implemented at a low temperature. In some cases, the growth temperature may be about less than about 400 degrees Celsius or other temperature compatible with CMOS fabrication. For instance, the growth temperature may be about 300 degrees Celsius or less. As with the examples described herein, the growth temperature may fall in a range from about 20 degrees Celsius to about 100 degrees Celsius. The growth temperature may correspond with the temperature measured at a thermocouple in the growth chamber. The growth temperature at the epitaxial surface may be slightly different. The growth temperature is accordingly approximated via the temperature measurement at the thermocouple. The growth and other temperatures addressed herein may thus vary in accordance with the manner in which the temperatures are measured. The growth or formation temperatures may vary in accordance with the composition of the piezoelectric layer and/or the epitaxial growth or other formation technique.

In some cases, the epitaxial growth procedure is implemented under a nitrogen-rich condition. For example, the nitrogen-to-metal flux ratio may be set in an act 418 in which the nitrogen flow is controlled. In some cases, the unbalanced flux ratio may be set to a highly or extremely nitrogen (N)-rich condition, such as a N-to-metal flux ratio of 2-to-1 or higher.

Control of the flux ratio between metal and nitrogen sources may be useful for improving the material quality of the piezoelectric layer. For instance, the N-rich growth conditions may be useful in connection with the growth of ScAlN to avoid Sc—Al intermetallic, Sc₃AlN perovskite phase formation, and/or other defects.

The piezoelectric layer is annealed in an act 420. The annealing may be implemented at a temperature higher than the growth or other formation temperature. In some cases, the annealing temperature exceeds the formation temperature by about 100 C to about 300 C. The anneal temperature may be less than about 400 C to remain compatible with CMOS components of the device being fabricated.

Such post-growth high-temperature annealing of ScAlN may be performed in-situ in the same growth or other formation chamber (e.g., the same MBE chamber) in an act 422. In other cases, the annealing is performed ex-situ in a chamber directed to annealing procedures. The annealing process may be implemented under high vacuum in an act 424 (e.g., in-situ in the growth chamber). In other cases, the annealing may be implemented either with nitrogen plasma radiation or under nitrogen gas, argon gas, or forming gas flow in an act 426.

The method 400 may include an act 428 in which one or more layers (e.g., semiconductor layers) are formed after growth and annealing of the piezoelectric layer. As a result, the layer(s) may be in contact with the piezoelectric layer. For instance, one or more III-nitride (e.g., GaN or AlGaN) or other semiconductor layers may be epitaxially grown in an act 430. The act 428 may be implemented in the same epitaxial growth or other chamber used to grow or otherwise form the piezoelectric layer. As a result, the substrate (and heterostructure) is not removed from the chamber between implementing the acts 412 and 428.

Alternatively or additionally, the act 428 includes an act 432 in which one or more metal or other conductive layers or structures are formed. For example, a metal layer may be deposited on the piezoelectric layer, such that the piezoelectric layer may be disposed between, and in contact with, two metal layers. The layers or structures may be deposited or otherwise formed. In some cases, the conductive structure is configured as an upper or top contact. For instance, the conductive structure may be a gate.

In some cases, the method 400 includes an act 434, in which the substrate is removed. The substrate may be partially or fully removed. With the substrate fully removed, the heterostructure becomes freestanding. In some cases, the act 434 includes implementation of an etching procedure, such as a wet or dry etch procedure. Alternatively or additionally, the substrate is removed mechanically. The manner in which the substrate is removed may thus vary accordingly.

The method 400 may include fewer, additional, or alternative acts. For example, one or more acts may be directed to forming other structures or regions of the device that includes the heterostructure. The nature of the regions or structures may vary in accordance with the nature of the device. In another example, the method 400 does not include an act 408 in which an oxide layer is removed from a substrate.

The order of the acts of the method 400 may differ from the example shown in FIG. 4. For example, contacts and/or other structures formed in the act 410 may be implemented after the growth of the piezoelectric layer.

A wide variety of devices may be fabricated by the method 400 of FIG. 4, and/or another method of fabricating a heterostructure having a piezoelectric layer as described herein.

Described herein are example implementations of scalable, post-growth high temperature annealing method to dramatically enhance the piezoelectric response of ScAlN and other III-nitrides and their alloys. For instance, examples of MBE grown SC_{0.18}A_{0.82}N establish that the piezoelectric coefficient d₃₃ was enhanced from 13.1 pC/N (for the as grown sample) to 23.7 pC/N, via implementation of a 2 hour annealing at 400° C., representing an 80% enhancement. No observable deterioration of the surface morphology was observed based on findings from atomic force microscopy (AFM) results, before and after annealing under the example conditions. Moreover, the d₃₃ value may be further enhanced by optimizing one or more parameters of the formation (e.g., growth or deposition process), including, for instance, Sc composition and/or the incorporation of other IIIB elements, e.g., Y and La.

The term “about” is used herein in a manner to include deviations from a specified value that would be understood by one of ordinary skill in the art to effectively be the same as the specified value due to, for instance, the absence of appreciable, detectable, or otherwise effective difference in operation, outcome, characteristic, or other aspect of the disclosed methods and devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A method of fabricating a heterostructure, the method comprising:
providing a substrate;
forming a piezoelectric layer supported by the substrate, the piezoelectric layer comprising a III-nitride material or an alloy thereof; and
annealing the piezoelectric layer at an anneal temperature higher than a temperature at which forming the piezoelectric layer is implemented by about 50 degrees Celsius to about 400 degrees Celsius.

2. The method of claim 1, wherein forming the piezoelectric layer comprises implementing a molecular beam epitaxy (MBE) procedure.

3. The method of claim 1, wherein annealing the piezoelectric layer is implemented in a vacuum.

4. The method of claim 1, wherein the temperature at which forming the piezoelectric layer is implemented is less than about 400 degrees Celsius.

5. The method of claim 1, wherein the anneal temperature is less than about 400 degrees Celsius.

6. The method of claim 1, wherein the anneal temperature falls in a range from about 250 degrees Celsius to about 450 degrees Celsius.

7. The method of claim 1, wherein the anneal temperature is higher than the temperature at which forming the piezoelectric layer is implemented by about 100 degrees Celsius to about 300 degrees Celsius.

8. The method of claim 1, wherein annealing the piezoelectric layer is implemented for a duration falling in a range from about 30 minutes to about 3 hours.

9. The method of claim 1, wherein the piezoelectric layer comprises AlN or AIBN.

10. The method of claim 1, wherein the piezoelectric layer comprises a III-nitride alloy, the III-nitride alloy comprising a Group IIIB element.

11. The method of claim 10, wherein the III-nitride alloy is ScAlN.

12. The method of claim 10, wherein the III-nitride alloy has a scandium composition above about 20%.

13. The method of claim 1, wherein the piezoelectric layer is in contact with the substrate.

14. The method of claim 1, wherein the substrate comprises silicon.

15. A method of fabricating a device, the method comprising:
providing a substrate;
growing a piezoelectric layer supported by the substrate at a growth temperature less than about 400 degrees Celsius, the piezoelectric layer comprising a III-nitride material or an alloy thereof; and
annealing the piezoelectric layer at an anneal temperature higher than the growth temperature by about 50 degrees Celsius to about 400 degrees Celsius.

16. The method of claim 15, wherein growing the piezoelectric layer comprises implementing a molecular beam epitaxy (MBE) procedure.

17. The method of claim 15, wherein annealing the piezoelectric layer is implemented in a vacuum.

18. The method of claim 15, wherein the anneal temperature is less than about 400 degrees Celsius.

19. The method of claim 15, wherein the anneal temperature falls in a range from about 250 degrees Celsius to about 450 degrees Celsius.

20. The method of claim 15, wherein annealing the piezoelectric layer is implemented for a duration falling in a range from about 30 minutes to about 3 hours.

21. The method of claim 15, wherein the piezoelectric layer comprises a III-nitride alloy, the III-nitride alloy having a scandium composition above about 20%.
